(19) United States
(12) Patent Application Publication
(10) Pub. No.: US 2025/0118944 A1
(43) Pub. Date: Apr. 10, 2025

(54) LASER DEVICE

(71) Applicant: TRUMPF Laser GmbH, Schramberg (DE)

(72) Inventor: Thomas Rataj, Berlin (DE)

(21) Appl. No.: 18/981,685

(22) Filed: Dec. 16, 2024

Related U.S. Application Data
(63) Continuation of application No. PCT/EP2023/066325, filed on Jun. 16, 2023.

(30) Foreign Application Priority Data
Jun. 20, 2022 (DE) 10 2022 115 317.7

(51) Int. Cl. H01S 5/024; H01S 5/02325; H01S 5/14

(52) U.S. Cl. CPC H01S 5/02415; H01S 5/02325; H01S 5/141

(57) ABSTRACT

A laser device includes a laser bench, and a semiconductor laser attached to the laser bench. The semiconductor laser is configured to emit laser light along a laser axis. The laser device further includes a first optical element for forming the laser light, a temperature element for controlling a temperature of the laser device, a holding element, and a Bragg grating body attached to the holding element and spaced apart from the laser bench.

### CROSS REFERENCE TO RELATED APPLICATIONS

This application is a continuation of International Application No. PCT/EP2023/066325 (WO 2023/247377 A1), filed on Jun. 16, 2023, and claims benefit to German Patent Application No. DE 10 2022 115 317.7, filed on Jun. 20, 2022. The aforementioned applications are hereby incorporated by reference herein.

### FIELD

Embodiments of the present invention relate to a laser device having a laser bench on which a semiconductor laser is provided for emitting a laser light along a laser axis.

### BACKGROUND

A laser device with a laser bench may deform when the temperature changes. In particular, temperature gradients and thermal expansion coefficients of different components of the laser device are the cause of such deformation. The deformation has a direct influence on the efficiency of the laser device, since the components of the laser device, such as optical elements and the semiconductor laser, are adjusted relative to the laser axis.

### SUMMARY

Embodiments of the present invention provide a laser device. The laser device includes a laser bench, and a semiconductor laser attached to the laser bench. The semiconductor laser is configured to emit laser light along a laser axis. The laser device further includes a first optical element for forming the laser light, a temperature element for controlling a temperature of the laser device, a holding element, and a Bragg grating body attached to the holding element and spaced apart from the laser bench.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a first exemplary embodiment in which the holding element is arranged on the optical elements; and

FIG. 2 shows a second exemplary embodiment in which the holding element is attached to the laser bench by means of spacer elements.

### DETAILED DESCRIPTION

Embodiments of the present invention provide a laser device with a laser bench, on which are attached a semiconductor laser for emitting a laser light along a laser axis, a first optical element for forming the laser light and a temperature element for controlling the temperature of the laser device, wherein the laser device has a holding element on which a Bragg grating body is attached that is spaced apart from the laser bench.

The Bragg grating body contains a Bragg grating that allows stabilization of the laser based on Bragg reflection.

The temperature element can be a Peltier element or a microchannel cooler. In order to enable advantageous temperature control by means of the temperature element, a thermistor can be positioned in particular in the vicinity of or in direct contact with the semiconductor laser. The thermistor can directly measure the temperature of the laser diode. A temperature signal from the thermistor is used by an evaluation unit of the control loop in which the thermistor and the temperature element are located to control the temperature of the temperature element.

The first optical element can be a lens for collimating the laser light.

Due to the spacing of the Bragg grating body apart from the laser bench, a deformation of the laser bench cannot have a direct effect on the position of the Bragg grating body. The holding element compensates for the deformation of the laser bench so that the desired relative position of the Bragg grating body to the laser axis is largely maintained. Minor deformations are still possible. However, such deformations only occur to an extent that does not affect the efficiency of the laser device.

Advantageously, the temperature element is mounted on a different, preferably opposite, side of the laser bench relative to the optical element. The laser bench is arranged in particular between the temperature element and the laser diode, so that heat transfer from the laser diode to the temperature element preferably takes place via the laser bench.

The holding element can be attached to a side of the optical element facing away from the laser bench. It can be mounted on the side of the optical element that faces away from the surface of the laser bench. This allows the Bragg grating body to be spaced apart from the laser bench depending on the height of the optical element. The height of the optical element refers to the surface of the laser bench on which the optical element is mounted.

In order to enable an efficient shaping of the laser light, a second optical element can be provided, wherein the Bragg grating body can be arranged between the two optical elements. In a special development, the holding element can be arranged on both optical elements, wherein the optical elements are of the same height.

In one exemplary embodiment, the Bragg grating body may be attached to a side of the holding element which faces the laser bench, wherein the Bragg grating body is spaced apart from a surface on which the optical element is attached. As a result, the Bragg grating body is not in direct contact with the laser bench, so that any deformation of the laser bench is compensated by the holding element.

In one exemplary embodiment, the holding element can have at least one spacer section which is attached to the laser bench so that the holding element is spaced apart from the laser bench. The spacer section is arranged between the holding element and the laser bench. Preferably, the spacer section has a height of 100 to 500 micrometers.

In an alternative exemplary embodiment, the Bragg grating body can be mounted on a side facing away from the laser bench. This exemplary embodiment can be combined with the previous exemplary embodiment so that, for example, two Bragg grating bodies are provided which are attached to different sides of one or more holding elements.

Advantageously, a third optical element is provided which is intended for collimating the laser light and is positioned between the first optical element and the semiconductor laser. The third optical element may be attached to the semiconductor laser so that it is not directly attached to the laser bench. The third optical element is provided for collimating the laser light in a direction perpendicular to the surface of the laser bench on which the first optical element stands. The first optical element produces a collimation of the laser light perpendicular to the collimation of the third optical element. The second optical element, in particular in the form of a thin-film polarizer, filters out the vertical polarization so that parallel polarization is allowed to pass through.

In particular, the Bragg grating body is spaced apart from the at least one optical element and from the laser bench, so that the Bragg grating body is only in direct contact with the holding element. The Bragg grating body can be spaced apart from each optical element so that there is no direct contact between an optical element and the Bragg grating body.

In one exemplary embodiment, the holding element is a housing section of the laser device. This means that a separate component is not required and the housing of the laser device can take over the function of the holding element.

Preferably, the holding element contains a ceramic material. This can be elastic. Preferably, the holding element is plate-shaped or rod-shaped.

A resonator is preferably formed between a cavity of the semiconductor laser and the Bragg grating body, which resonator extends along the laser axis and stabilizes a laser mode of the laser light. A rear facet of the cavity of the semiconductor laser can serve as one boundary of the resonator, while the Bragg grating of the Bragg grating body forms the other boundary. Preferably, the output facet of the laser from which the laser light is emitted has an anti-reflective coating. The rear facet is the rear wall of the cavity within the semiconductor laser, which has an emission region on the output facet of the semiconductor laser, wherein the emission region is opposite the rear facet. The laser light exits the semiconductor laser from the emission region. The external resonator, which enables narrow-band operation, is formed between the rear facet of the cavity of the semiconductor laser and the Bragg grating of the Bragg grating body. The resulting wavelength range is 1 to 100 pm, in particular 1 to 50 pm.

Exemplary embodiments are described below with reference to the associated drawings. Direction indications in the following explanation are to be understood according to the reading direction of the drawings.

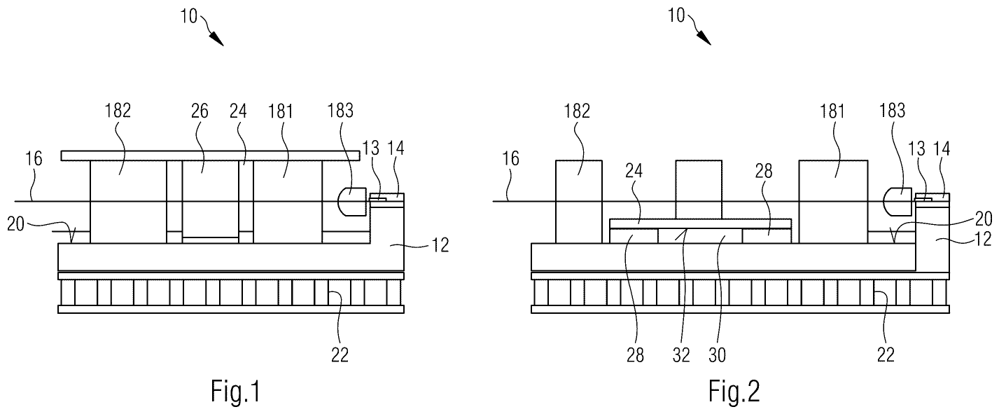

FIG. 1 shows a first exemplary embodiment in which the holding element is arranged on the optical elements.

FIG. 2 shows a second exemplary embodiment in which the holding element is attached to the laser bench by means of spacer elements.

The figures show a laser device 10 which comprises a laser bench 12 on which a semiconductor laser 14 is attached, which is intended to emit a laser light along a laser axis 16. A first optical element 181 and a second optical element 182 are arranged along the laser axis 16 and are intended for shaping the laser light. The first optical element 181 is arranged between the second optical element 182 and the semiconductor laser 14.

The optical element 181 is provided for collimating the laser light along the laser axis 16. Furthermore, a third optical element 183 is provided which is intended for collimating the laser light. It is positioned between the first optical element 181 and the semiconductor laser 14. The third optical element 183 may be attached to the semiconductor laser 14 so that it is not directly attached to the laser bench 12. Alternatively, the third optical element 183 can also be arranged directly on the laser bench 12.

The third optical element 183 is provided for collimating the laser light in a direction perpendicular to the surface of the laser bench 12 on which the first optical element 181 stands. The first optical element 181 produces a collimation of the laser light perpendicular to the collimation of the third optical element 183. The second optical element 182, in particular in the form of a thin-film polarizer, filters out the vertical polarization so that parallel polarization is allowed to pass through.

The optical elements 181, 182, 183 and the semiconductor laser 14 are arranged on a common side of the laser bench 12, wherein the first and the second optical element 181, 182 are mounted on a surface 20 of the laser bench 12.

A temperature element 22 is mounted on an opposite side of the laser bench 12 for regulating the temperature of the laser device 10. The temperature element 22 can be a Peltier element or a microchannel cooler. It is in contact with the surface of the laser bench 12. The laser bench 12 is arranged between the temperature element 22 and the laser diode 14 so that heat transfer from the laser diode 14 to the temperature element 22 takes place via the laser bench 12.

The laser device 10 has a holding element 24 which is provided for a Bragg grating body 26. The Bragg grating body 26 is attached to the holding element 24, wherein it is spaced apart from the laser bench 12 such that it has no direct contact with the laser bench 12.

The Bragg grating body contains a Bragg grating that allows stabilization of the laser based on Bragg reflection.

Due to the spacing of the Bragg grating body 26 apart from the laser bench 12, a deformation of the laser bench 12 cannot have a direct effect on the position of the Bragg grating body 26. The holding element 26 compensates for the deformation of the laser bench 12 so that the desired relative position of the Bragg grating body 26 to the laser axis 16 is largely maintained.

The holding element 24 preferably has a ceramic material that is elastic. The holding element 24 is plate-shaped or rod-shaped.

An external resonator is preferably formed between a cavity 13 of the semiconductor laser 14 and the Bragg grating body 26, which external resonator extends along the laser axis 16. The resonator stabilizes a laser mode of the laser light, which is predetermined by the Bragg grating. The Bragg grating acts as an output element of the external resonator, so that only a very narrow-band laser line in the picometer range, in particular 1 to 100 pm, preferably 1 to 50 pm, is emitted. The semiconductor laser 14 contains a cavity which has a rear facet and an output facet opposite the rear facet, wherein both facets are arranged along the laser axis 16. The rear facet is the rear wall of the cavity 13 of the semiconductor laser 14, which is opposite an emission region on the output facet of the semiconductor laser 14. The laser light exits the emission region. The rear facet represents the first boundary with respect to the laser axis 16 of the resonator, while the Bragg grating of the Bragg grating body 26 forms a second boundary.

FIG. 1 shows a holding element 24 in a laser device 10, which is arranged on the first and second optical elements 181, 182, so that the optical elements 181, 182 are arranged between the holding element 24 and the laser bench 12. The holding element 24 is attached to a side of the respective optical element 181, 182 facing away from the laser bench 12.

The Bragg grating body 26 projects from the holding element 24 in the direction of the laser bench 12. The Bragg grating body 26 does not touch the laser bench 12. Furthermore, the Bragg grating body 26 is arranged between the first and second optical elements 181, 182, wherein all optical elements 181, 182, 183 and the Bragg grating body 26 are arranged along the laser axis 16. Preferably, the two optical elements 181, 182 are of equal height and the holding element 24 is aligned parallel to the surface 20 of the laser bench 12.

The Bragg grating body 26 does not touch the optical elements 181, 182. The Bragg grating body 26 protrudes freely from the holding element 24.

In another embodiment, only the first optical element 181 can shape the laser light. Instead of the second optical element 182, a support element can be used that does not shape the laser light. For example, a material that is transparent to the laser light can be used, which also has a recess through which the laser light can pass unhindered. For example, a glass cuboid with a hole can be used, wherein the hole represents the recess.

FIG. 2 shows a second exemplary embodiment in which the holding element 24 is mounted with at least one spacer section 28 on the laser bench 12 such that the holding element 24 is spaced apart from the surface 20 of the laser bench 24. The spacer section 28 is arranged between the holding element 24 and the laser bench 12 and can have the shape of a disk. Preferably, the spacer section 28 has a height of 100 to 500 micrometers. Preferably, a plurality of spacer sections 28 are provided, which are arranged on the underside of the holding element 24, so that a free space 30 is formed between the spacer sections 28 of the surface 20 of the laser bench 12 and an underside 32 of the holding element 24.

The Bragg grating body 26 is mounted on a side facing away from the laser bench 12. The Bragg grating body 26 is also free-standing and spaced apart from the laser bench 12. The Bragg grating body 26 protrudes upwards. It is arranged between the first and the second optical element 181, 182.

Both exemplary embodiments can be realized with only one optical element 181. Furthermore, the exemplary embodiments can be combined with one another, so that, for example, two Bragg grating bodies 26 are provided, in particular in connection with several semiconductor lasers 14. The Bragg grating bodies 26 can be attached to different sides of one or more holding elements 24.

Furthermore, the holding element 24 can alternatively be formed by a housing section of a housing of the laser device 10.

Overall, the second optical element 182 can also be dispensed with.

A focusing lens can be arranged after the second optical element 182, or if the second optical element is omitted, after the Bragg grating body 26, which couples the laser light into a waveguide. The focusing lens can be attached to the housing of the laser device 10. This can be glued to the housing. As a result, it is decoupled from the structure of the laser bench 12. Alternatively, the focusing lens can be glued directly onto the laser bench as the last beam-forming element before the waveguide.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A laser device, comprising:
a laser bench,
a semiconductor laser attached to the laser bench, the semiconductor laser configured to emit laser light along a laser axis,
a first optical element for forming the laser light,
a temperature element for controlling a temperature of the laser device,
a holding element, and
a Bragg grating body attached to the holding element and spaced apart from the laser bench.

2. The laser device according to claim 1, wherein the temperature element is mounted on a different side of the laser bench than the first optical element.

3. The laser device according to claim 1, wherein the holding element is attached to the first optical element on a side facing away from the laser bench.

4. The laser device according to claim 1, further comprising a second optical element, wherein the Bragg grating body is arranged between the first optical element and the second optical element.

5. The laser device according to claim 1, wherein the Bragg grating body is attached to a side of the holding element that faces the laser bench, wherein the Bragg grating body is spaced apart from a surface on which the first optical element is attached.

6. The laser device according to claim 1, wherein the holding element has at least one spacer section that is attached to the laser bench, so that the holding element is spaced apart from the laser bench.

7. The laser device according to claim 6, wherein the spacer section has a height of 100 to 500 micrometers.

8. The laser device according to claim 6, wherein the Bragg grating body is attached to the holding element on a side of the holding element facing away from the laser bench.

9. The laser device according to claim 1, further comprising a third optical element configured to collimate the laser light and positioned between the first optical element and the semiconductor laser.

10. The laser device according to claim 1, wherein the Bragg grating body is spaced apart from the first optical element and from the laser bench, so that the Bragg grating body is only in direct contact with the holding element.

11. The laser device according to claim 1, wherein the holding element is a housing section of the laser device.

12. The laser device according to claim 1, wherein the holding element contains a ceramic material.

13. The laser device according to claim 1, wherein the holding element is plate-shaped or rod-shaped.

14. The laser device according to claim 1, wherein a resonator is formed between a cavity of the semiconductor laser and the Bragg grating body along the laser axis, which stabilizes a laser mode of the laser light.
